(19) United States
(12) Patent Application Publication
(10) Pub. No.: US 2026/0098614 A1
(43) Pub. Date: Apr. 9, 2026

(54) METHOD FOR PIPELINE CORROSION PREDICTION AND MAINTENANCE

(71) Applicant: MATRIX JVCO LTD trading as AIQ, Abu Dhabi (AE)

(72) Inventors: Mouna ZAIDANI, Abu Dhabi (AE); Zaynab HABIBI, Abu Dhabi (AE); Umar ASIF, Abu Dhabi (AE); Mohamed AMRI, Abu Dhabi (AE); Rachid BELMESKINE, Abu Dhabi (AE)

(73) Assignee: MATRIX JVCO LTD trading as AIQ, Abu Dhabi (AE)

(21) Appl. No.: 19/115,074

(22) PCT Filed: Sep. 30, 2022
(86) PCT No.: PCT/IB2022/059349

§ 371 Date: Mar. 25, 2025

(51) Int. Cl. F17D 5/00; G06F 30/27

(52) U.S. Cl. CPC F17D 5/00; G06F 30/27

(57) ABSTRACT

A computer-implemented method for predicting corrosion of a pipeline comprises the steps of: generating, using a physical simulation model, a physical flow profile of the pipeline based on at least a part of an inspection profile of the pipeline; predicting, using a machine learning model, a future corrosion profile of the pipeline including at least one future corrosion feature based on at least a part of the inspection profile of the pipeline and the physical flow profile of the pipeline; wherein the inspection profile includes operating data of the pipeline comprising inspection data from at least one physical inspection of the pipeline. In addition, a corresponding training method, model, computer program as well as data processing devices are disclosed.

### FIELD OF THE INVENTION

The present disclosure relates to a computer-implemented method, a data processing device and a computer program for predicting corrosion of a pipeline. In addition, the present disclosure relates to a training method of a machine learning model for predicting a corrosion profile of a pipeline.

### BACKGROUND

Pipelines are one of the largest systems of energy infrastructures in the oil and gas industry, as efficient oil and gas transport would be impossible without the presence of a reliable network of pipelines. Pipelines are a safe way to deliver oil and gas products, as they are usually made of carbon steel, and are purpose-built to carry commodities like oil, gas and refined products, both in offshore and onshore environments. However, this does not mean that they are immune to harm. In fact, corrosion is a potential danger to the pipeline's reliability and serviceability.

Maintaining the integrity and reliability of pipelines is a primary role in minimizing the environmental impact and ensuring the productivity of modern systems and oil and gas production fields. Depending on the circumstances of use and the products being transported, pipelines may corrode in different locations and for different reasons. For example, the internal surface can corrode at the bottom due to accumulation of heavy components, while its top may corrode due to contact with water vapor. The outside surface may corrode from the top as the insulation collects condensation from the air. In order to avoid pipeline and equipment failure, it is crucial to closely monitor the pipeline corrosion behavior and the extent of pipeline wall thickness reduction, so repairs can be conducted in a timely manner.

To monitor the corrosion behavior of pipelines, different pipeline wall thickness measurement techniques have been developed over the previous years. These include approaches such as measuring the thickness at random or specific locations based on the most susceptible locations to severe corrosion and a corresponding loss of wall thickness, or along the entire pipeline. These measurement technologies include different measurement techniques like imaging by radiography (RT) or X-rays, or ultrasonic measurement for the examination of pipeline walls from the exterior. These techniques are very costly, from both the labor and equipment costs. Unfortunately, these monitoring technologies are not pipeline agnostic and therefore cannot be applied to all type of pipelines due to their different geometry or construction. Measurement's sampling must therefore be used on an extensive number of pipelines in relatively recent plants and pipeline systems. Moreover, the pipeline should be accessible to perform these techniques, so for the underground segments/joints of the pipelines, excavation is required to obtain these measurements.

‘In line inspection’ (ILI) is considered the most widely used technology for pipelines wall thickness measurement. This technique uses a pigging vehicle referred to as a ‘pig’ that travels along the entire length of the pipeline. This pigging tool repeatedly indirectly measures the pipeline wall thickness using transducers while travelling along the entire pipeline length. Different technology measurements are used in ILI, including ultrasonic energy and magnetic flux leakage technique referred to as ‘MFL’. It measures the wall thickness through measuring the extent of which magnetic flux can be induced into the pipeline wall.

In order to ensure pipeline integrity, ILIs are performed periodically using smart pigging tools to detect pipeline defects such as corrosion and cracks. However, as resources for ILIs are limited, a way for efficient resource usage is required. One way of achieving this is in predicting the corrosion state (e.g., by means of predicting the wall thickness of the pipeline).

De Masi et al.: “Neural network predictive model of pipeline internal corrosion profile” state that due to the complex interaction of different mechanisms (e.g., water, electrochemistry, steel composition) traditional models (e.g., deterministic or statistical models) are not able to correctly and reliably predict the corrosion process of a pipeline. In order to solve this problem, De Masi et al. present an artificial neural network (ANN) based model to correctly predict the presence of metal loss and corrosion rate along the pipeline. The presented ANN model integrates the geometrical profile of a real pipeline (i.e., elevation, inclination, and concavity), flow simulations of multiphase flow velocity and transport as well as deterministic models (i.e., theoretical mechanistic models like the de Waard model and the NORSOK model).

Even though De Masi et al. mention that the corrosion development is a highly complex phenomenon, which they try to model by using different types of input data, their model still bases on the assumption that corrosion develops in a kind of deterministic way for a given input (e.g., a pipeline of a given geometry with corresponding flow parameters corrodes in a certain way). However, from a physical point of view, this assumption is incorrect as corrosion typically develops in a non-deterministic manner.

Against this background, there is a need for a method for accurate and reliable predicting corrosion of a pipeline allowing for an efficient maintenance of the pipeline regarding integrity and resource usage (i.e., efficient usage of available ILI resources).

### SUMMARY OF THE INVENTION

The above-mentioned problem is at least partly solved by a computer-implemented method according to aspect 1, by a computer-implemented method according to aspect 14, by a machine learning model according to claim 17, by a data processing device according to aspect 18 and a computer program according to aspect 19.

A 1st aspect of the present invention refers to a computer-implemented method for predicting corrosion of a pipeline, wherein the method comprises the steps of: generating (100), using a physical simulation model, a physical flow profile (110) of the pipeline based on an at least a part of an inspection profile (400) of the pipeline; predicting (200), using a machine learning model, a future corrosion profile of the pipeline including at least one future corrosion feature based on at least a part of the inspection profile of the pipeline and the physical flow profile of the pipeline; wherein the inspection profile (400) includes operating data of the pipeline comprising inspection data from at least one physical inspection of the pipeline.

Predicting the corrosion of a pipeline based on a physical flow profile and an inspection profile, which comprises operating data of a physical inspection, allows accurately predicting the corrosion of the pipeline. This is because the model considers a combination of pipeline specific simulation and real inspection data for prediction. This may lead to improved prediction results.

According to a 2nd aspect in the 1st aspect, the method further comprises determining (300) an operation instruction for the pipeline based on the future corrosion profile.

An operation instruction determined based on the accurate prediction allows to ensure pipeline integrity and safety as well as improved resource usage in terms of efficiency (e.g., efficient scheduling of ILI inspections).

According to a 3rd aspect in any one of the 1st to 2nd aspect, the physical simulation model used for generating the physical flow profile is a computational fluid dynamic, CFD, model and/or a finite element analysis, FEA, model; and/or wherein the physical flow profile (110) includes at least one of: a flow distribution of the pipeline; a velocity profile of the pipeline; a wall shear stress, WSS, of the pipeline; a pressure profile of the pipeline; a pressure drop of the pipeline; and/or a temperature profile of the pipeline.

Generating a detailed physical flow profile increases the precision of modelling the physical impact on the corrosion development of the pipeline. Accordingly, the corrosion prediction accuracy may be improved.

According to a 4th aspect in any one of the 1st to 3rd aspect, the inspection profile of the pipeline further includes at least one of: geometric configuration data of the pipeline; historical corrosion data of the pipeline; and/or chemical composition data of a medium flowing through the pipeline.

Geometric configuration data describes physical or environmental aspects of the pipeline. As geometric configurations of a pipeline have a certain impact on the corrosion development, providing this information increases the accuracy of the corrosion prediction. As the chemical composition data of the medium flowing through the pipeline has a huge impact on the corrosion development, providing this information increases the accuracy of the corrosion prediction. Providing historical corrosion data of the pipeline may provide information on an already existing corrosion distribution along the pipeline, which increases the accuracy of the corrosion prediction.

According to a 5th aspect in the 4th aspect, the geometric configuration data of the pipeline comprises at least one of: a pipeline type; a coating material of the pipeline; a construction configuration of the pipeline comprising one or more segments and/or joints each having a corresponding ID; and/or one or more of: a design life, geographical coordinates, a length, a diameter, a nominal thickness, material, height and/or elevation angle of the pipeline.

Providing detailed information about the geometric configuration of the pipeline, for example the pipeline type (e.g., gathering, transmission, distribution type, or above or under water), may provide additional information about the pipeline construction and its associated impact on the corrosion behavior (e.g., a subsea pipeline may be associated with a different corrosion behavior than a land pipeline). Therefore, including this information increases the accuracy of modelling the pipeline and thus predicting its corrosion.

According to a 6th aspect in any one of the 1st to 5th aspect, each inspection data comprises at least one of: a pipeline inlet injection pressure, velocity, temperature and/or mass flow rate; a pipeline design pressure and or temperature allowance; a fluid mixture density, viscosity and/or temperature; a pipeline outlet pressure, velocity and/or mass flow rate; and/or a pipeline internal wall roughness.

Providing detailed inspection data of the pipeline may allow to compensate for a certain inaccuracy of the physical simulation model. Therefore, an improved representation of the actual physical impact on the pipeline is provided resulting in a more accurate corrosion prediction.

According to a 7th aspect in any one of the 4th to 6th aspect, the historical corrosion data comprises inspection data from at least one physical inspection of the pipeline; wherein each inspection data comprises at least one historical corrosion feature; and wherein each historical corrosion feature comprises at least one of: x, y and/or z cartesian coordinates on the pipeline; geographical coordinates; circumferential position on the pipeline; a corrosion type being; information about the position of the corrosion being internal or external on the pipe; dimensional information; a location class, a upstream distance from a closest girth weld; a join ID and length; and/or a wall nominal thickness.

Providing detailed information about the historical corrosion data of the pipeline allows for an improved representation of the present corrosion distribution along the pipeline. Therefore, a more accurate starting point for the corrosion prediction is provided.

According to an 8th aspect in the 7th aspect, the method further comprises: determining, for each historical corrosion feature of an inspection data of a first physical inspection of the pipeline, a corrosion growth rate, a wall metal loss and/or an exposure time; adding the corrosion growth rate, the wall metal loss and/or the exposure time to the corresponding historical corrosion feature; and wherein determining the corrosion growth rate, the wall metal loss and/or the exposure time of the corresponding historical corrosion feature comprises: comparing the corresponding historical corrosion feature with inspection data of a second physical inspection; and wherein the second physical inspection has been conducted prior to the first physical inspection.

Determining corrosion development information like the exposure time and corresponding wall metal loss for all corrosion features, ensures that the corrosion development of a corrosion feature is kept up to date. As a result, model predictions on outdated (i.e., unreliable) data is avoided, increasing the reliability of the prediction.

According to a 9th aspect in any one of the 4th to 8th aspect, the chemical composition data comprises inspection data from at least one physical inspection of the pipeline; and wherein each inspection data comprises at least one of: CO₂ concentration; H₂S concentration and/or H₂O content percentage.

As the chemical composition of the medium flowing through the pipeline has a huge impact on the corrosion behavior, providing detailed information thereon may increase the accuracy of the corrosion prediction.

According to a 10th aspect in any one of the 1st to 9th aspect, the method further comprises: determining that new inspection data of a physical inspection of the pipeline is available; generating an updated inspection profile by updating the inspection profile of the pipeline by adding the new inspection data to the inspection profile of the pipeline.

Updating the inspection profile of the pipeline once new inspection data is available avoids corrosion predictions being conducted based on outdated (i.e., unreliable) data, which increases the reliability of the prediction.

According to an 11th aspect in any one of the 1st to 10th aspect, each future corrosion feature of the future corrosion profile includes least one of: a location of a corrosion; a corrosion growth rate; a corrosion depth; and/or a corrosion severity level.

Based on the predicted information, e.g., the corrosion severity level, a suitable operating instruction may be determined, which ensures pipeline integrity.

According to a 12th aspect, in any one of the 1st to 11th aspect, the machine learning model is trained according to the following steps: inputting training data to the machine learning model to train the machine learning model; wherein the training data includes a plurality of time-series data samples, each data sample comprising: a pipeline inspection profile of a pipeline and a physical flow profile of the pipeline; and a corresponding future corrosion profile of the pipeline.

According to a 13th aspect, in the 12th aspect, the machine learning model is retrained using the updated inspection profile.

A 14th aspect refers to a computer-implemented method for training a machine learning model for predicting a future corrosion profile of a pipeline, wherein the method comprises: inputting training data to the machine learning model to train the machine learning model; wherein the training data includes a plurality of time-series data samples, each data sample comprising: a pipeline inspection profile of the pipeline and a physical flow profile of the pipeline; and a corresponding future corrosion profile of the pipeline.

According to a 15th aspect in the preceding aspect, training the machine learning model further comprises: learning, by the machine learning model, to predict the corresponding future corrosion profile of the pipeline based on the pipeline inspection profile and the physical flow profile of the pipeline.

According to a 16th aspect in any one of the 12th to 13th aspect, training the machine learning model further comprises validating the machine learning model, wherein validating comprises: inputting test data into the machine learning model, the test data comprising a plurality of time-series test data samples, wherein each test data sample comprises at least an inspection profile and a physical flow profile; receiving prediction data from the machine learning model, wherein prediction data comprises one predicted future corrosion profile for each test data sample; determining a prediction accuracy of the machine learning model based on the prediction data; and determining based on the prediction accuracy that training of the machine learning model is finished.

According to a further aspect, the machine learning model of the 1st to 13th aspect is trained according to the method of any one of the 14th to 16th aspect.

A 17th aspect refers to a machine learning model for predicting a future corrosion profile of a pipeline trained according to the method of any one of the 14th to 16th aspect.

An 18th aspect refers to a data processing device comprising means configured to perform a method according to the 1st to 13th or 14th to 16th aspect.

A 19th aspect refers to a computer program comprising instructions, which when executed by a computer, causes the computer to carry out a method according to the 1st to 13th or 14th to 16th aspect.

### BRIEF DESCRIPTION OF THE DRAWINGS

Various aspects of the present invention are described in more detail in the following by reference to the accompanying figures without the present invention being limited to the embodiments of these figures.

FIG. 1 illustrates an overview of a process according to aspects of the present invention.

FIG. 2 illustrates a flow chart of a method for predicting corrosion of a pipeline according to aspects of the present invention.

FIG. 3 illustrates a graphical user interface displaying results achieved by the process according to aspects of the present invention.

FIG. 4 illustrates an overview of an improved workflow according to aspects of the present invention.

### DETAILED DESCRIPTION

In the following, certain aspects of the present invention are described in more detail.

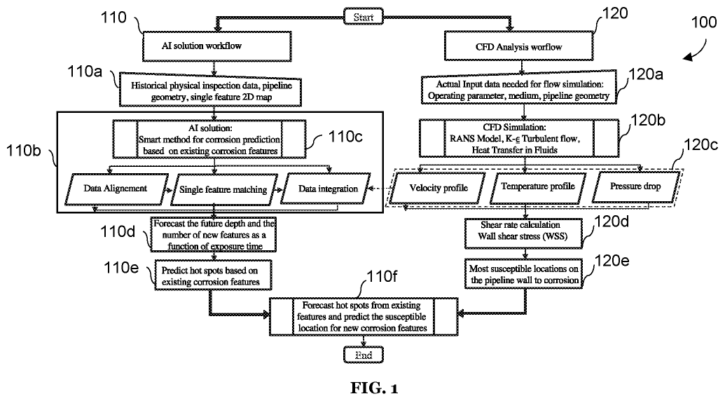

FIG. 1 illustrates an overview of a process 100 according to aspects of the present invention used for efficiently predicting the corrosion of a pipeline. The process 100 is based on an artificial intelligence (AI) solution workflow 110 and a physical flow model analysis in terms of a computational fluid dynamic (CFD) analysis workflow 120. Both workflows may be executed in parallel. The input data on which the process operates is referred to as inspection profile. A pipeline for which the corrosion is to be predicted is associated with a corresponding inspection profile. The inspection profile includes information describing a current state of the pipeline. The inspection profile may include operating data of the pipeline (e.g., comprising inspection data from at least one physical inspection of the pipeline), geometric configuration data of the pipeline (e.g., a pipeline type, coating material of the pipeline, a construction configuration of the pipeline), historical corrosion data of the pipeline (e.g., historical corrosion features) and/or chemical composition data of a medium flowing through the pipeline (e.g., CO₂ concentration; H₂S concentration and/or H₂O content percentage).

While both workflows operate on the input data, in the embodiment according to FIG. 1, each workflow only operates on certain parts 110a, 120a of the input data. For example, the CFD analysis workflow 120 may only use a part 120a of the inspection profile (e.g., operating data of the pipeline, chemical composition data of the medium flowing through the pipeline and the geometric configuration data of the pipeline) as input. In step 120b, a CFD simulation (or a finite element analysis (FEA) model or other suitable physical flow model simulations) may use the part 120a of the inspection profile to generate (i.e., simulate) a physical flow profile 120c of the pipeline. The generation in step 120b may be based, for example on a Reynolds-averaged Navier-Strokes (RANS) model, K-epsilon turbulence model and/or based on a Heat Transfer in Fluids model. The generated physical flow 120c profile may for example include a flow distribution of the profile, a velocity profile of the pipeline, optionally a wall shear stress (WSS) of the pipeline, a pressure profile of the pipeline, a pressure drop of the pipeline and/or a temperature profile. Accordingly, the physical flow profile 120c provides information about how the medium flows through the pipeline as well as how this effects the pipeline. This may later allow to draw conclusions about locations in the pipeline, which may be susceptible to corrosion.

Optionally, the CFD analysis workflow 120 may comprise step 120d, which may conduct a shear rate calculation to determine the WSS. The WSS may then, optionally, be used in step 120e together with the physical flow profile 120c (assuming that the physical flow profile 120c does not comprise the WSS) to determine locations of the pipeline wall that are most susceptible to corrosion.

The AI solution workflow 110 may also only use a part 100a of the inspection profile as input (e.g., the operating data of the pipeline, the geometric configuration data of the pipeline and the historical corrosion data of the pipeline (e.g., in form of a single feature 2D map). Afterwards, in step 110b, a pre-processing step may be triggered. As a first sub-step 110c, an AI-based method for corrosion prediction based on existing corrosion features may be initiated. Furthermore, in step 110b, the part 110a of the inspection profile may be aligned, feature-matched and integrated with at least a part of the physical flow profile 120c generated by the CFD analysis workflow 120 (indicated by the dotted arrow from the CFD analysis workflow 120 on the right side to the AI solution workflow 110 on the left side). This may be referred to as data integration, while data alignment and single feature matching ensures inter alia data integrity of the inspection profile of the profile. The corresponding input data (i.e., the part 110a of the inspection profile and the physical flow profile 120c of the pipeline) may be inputted into a machine learning model and processed in step 110d for predicting (or forecasting) a future depth and a number of new corrosion features (e.g., indicating locations of the pipeline where corrosion is expected to occur in the future) as a function of exposure time.

Then, in step 110e, corrosion hot spots based on existing corrosion features are predicted. The output of steps 110d and 110e may be referred to as a predicted future corrosion profile. The predicted future corrosion profile may include one or more corrosion features (e.g., the future corrosion depth of old/existing corrosion features and new corrosion features may be forecast). Each corrosion feature may include information about a location of a corrosion of the corrosion feature, a corrosion growth rate of the corrosion feature, a corrosion depth of the corrosion feature and/or a corrosion severity level of the corrosion feature. In step 110e, based on the future corrosion profile, hot spots may be predicted in which a high amount of corrosion will exist. A corrosion feature having a high corrosion severity level may be referred to as hot spots.

Optionally, the WSS as well as information about locations most susceptible to corrosion may be retrieved in step 110f as an output of step 120e.

Finally, in step 110f, the predicted hot spots and the locations susceptible for new corrosion features may be available. Based on the information provided by the predicted future corrosion profile an operation instruction for the pipeline may be determined.

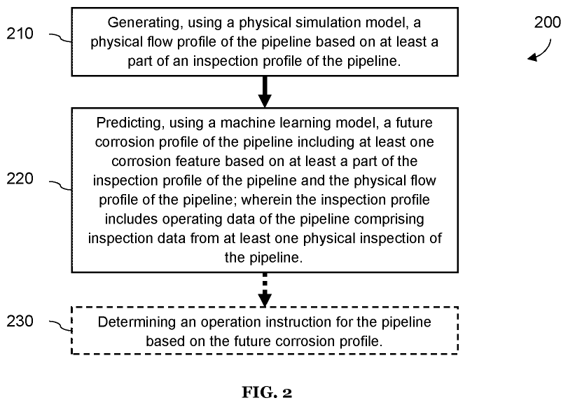

FIG. 2 illustrates a flow chart of a method 200 for predicting corrosion of a pipeline according to aspects of the present invention. The method 200 may be based on the process 100. In step 210, a physical flow profile of the pipeline based on at least a part of an inspection profile of the pipeline may be generated. Step 210 may refer to the CFD analysis workflow 120 of the process 100. The physical simulation model used for generating the physical flow profile may be a CFD and/or a FEA model. The physical flow profile may include at least one of a flow distribution of the pipeline, a velocity profile of the pipeline, a wall shear stress, WSS, of the pipeline, a pressure profile of the pipeline, a pressure drop of the pipeline and/or a temperature profile of the pipeline. Based on the physical flow profile, the above-mentioned physical parameters (e.g., temperature, WWS, pressure etc.) may be determined for each location along the pipeline.

The inspection profile may include operating data of the pipeline comprising inspection data from at least one physical inspection of the pipeline. The inspection data from one physical inspection of the pipeline may comprise at least one of a pipeline inlet injection pressure, velocity, temperature and/or mass flow rate, a pipeline design pressure and or temperature allowance, a fluid mixture density, viscosity and/or temperature, a pipeline outlet pressure, velocity and/or mass flow rate and/or a pipeline internal wall roughness. The operating data comprising the inspection data obtained from a physical inspection may be time-stamped. Accordingly, the operating data may comprise the above-mentioned operating parameters (e.g., inlet injection pressure, velocity etc.) associated with a corresponding time-stamp of a corresponding physical inspection. In some embodiments, the method may continuously update the inspection profile once new operating data is available. For example, should new inspection data from a newly conducted physical inspection provide new operation data, the new operation data may be added to the existing operation data. In an example in which the operation data is time-stamped, one can describe adding a new operation data to the existing operation data, as adding a new time-stamped operation data to the existing time-series of time-stamped operation data.

Furthermore, the inspection profile may include a geometric configuration data of the pipeline. The geometric configuration data of the pipeline may comprise at least one of a pipeline type, a coating material of the pipeline, a construction configuration of the pipeline comprising one or more segments and/or joints each having a corresponding ID. Each segment and/or joint may comprise one or more of a design life, geographical coordinates, a length, a dimeter, a nominal thickness, material, height and/or elevation angle of the pipeline. The geometric configuration data of the pipeline may be automatically updated once new geometric configuration data of the pipeline is available (e.g., provided by inspection data of a newly conducted physical inspection). For example, should the pipeline have been coated with a new/different material, the corresponding information about the coating material of the pipeline will be updated accordingly.

The inspection profile may in addition or alternatively include chemical composition data of a medium flowing through the pipeline. The chemical composition data may comprise inspection data from at least one physical inspection of the pipeline, wherein inspection data from a physical inspection comprises at least one of CO2 concentration; H2S concentration and/or H2O content percentage. The chemical composition data comprising the inspection data obtained from a physical inspection may be time-stamped. Accordingly, the chemical composition data may comprise the above-mentioned parameters (e.g., CO2 concentration etc.) associated with a corresponding time-stamp of a corresponding physical inspection. The chemical composition data may be automatically updated once new chemical composition data is available (e.g., provided by inspection data of a newly conducted physical inspection). For example, should the CO2 concentration of the medium flowing through the pipeline change, the chemical composition data may be updated accordingly. In an example in which the chemical composition data may be time-stamped, updating the chemical composition data may be described as adding a new time-stamped chemical composition data to the existing time-series of time-stamped chemical composition data.

The inspection profile may in addition or alternatively include historical corrosion data of the pipeline. The historical corrosion data may comprise inspection data from at least one physical inspection of the pipeline, wherein inspection data from a physical inspection comprises at least one historical corrosion feature. A historical corrosion feature may be described by/comprise at least one of cartesian coordinates (e.g., x, y and/or z, wherein z may correspond to a height of the corrosion feature) on the pipeline, geographical coordinates (e.g., GPS), circumferential position on the pipeline (i.e., o'clock position), a corrosion type (e.g., pitting, metal loss etc.), information about the position of the corrosion (e.g., whether the corrosion is internal or external on the pipe), dimensional information (e.g., depth, width, length of the corrosion feature), a location class (e.g., on weld, close to weld, joint etc.), an upstream distance from a closest girth weld, a joint ID and length (i.e., on which joint of which length the corrosion has occurred) and/or a wall nominal thickness.

The inspection data may be time-stamped. Accordingly, each of the historical corrosion features may be associated with a time-stamp of a corresponding physical inspection. Based on the historical corrosion data, a corrosion development information (e.g., corrosion growth rate, a wall metal loss and/or a exposure time) may be determined for each historical corrosion feature. This corrosion development information may then be added to the historical corrosion feature for further information value. Determining the corrosion development information may be done by comparing a historical corrosion feature from a first physical inspection to the corrosion feature from a second physical inspection, wherein the second physical inspection was conducted prior to the first physical inspection. This means that the corrosion development of a single historical corrosion feature is determined by comparing it at two different point in times. For example, the second physical inspection was done on March 1st and provides the information about a corrosion feature having dimensions of 10×10 cm (width and length) and 5 cm (depth into the pipe). In the example, the first physical inspection may then be done on May 1st of the same year. This inspection may provide the information about the same corrosion feature now having dimension of 15×15 cm (width and length) and 10 cm (depth into the pipe). A possible way of ensuring that the same corrosion features are compared (i.e., identifying the same corrosion feature in two different inspections), may be by comparing their coordinates, circumferential position, geographical coordinates and/or the ID of the joint on which the corrosion feature occurred. Based on the information provided by the second and first physical inspection, a corrosion growth rate may be determined by comparing the dimensions of the corrosion feature. In this example, the corrosion growth rate may be determined to be 50%. An exposure time may be the time between the second and first physical inspection, which in this example may be 1 month. Other time units (e.g., hours, weeks, years etc.) are also possible. The determining of the corrosion development information may be done between each corresponding corrosion features and between each pair (i.e., two) of physical inspections. This way, corrosion development information for each corrosion feature over the entire lifetime of the corrosion feature (i.e., since the corrosion feature was firstly discovered by a physical inspection) may be obtained (i.e., automatically determined/computed and stored i.e., added to the information about the corresponding corrosion feature).

The historical corrosion data of the pipeline may be updated once new corrosion data is available (e.g., provided by inspection data of a newly conducted physical inspection). Apart from adding the new inspection data to the historical corrosion data of the pipeline, the method may determine the corrosion development information for each corrosion feature of the new corrosion data by identifying the corresponding historical corrosion feature. As described above, this may be done by comparing their coordinates, dimensions etc. Identifying the corresponding corrosion feature may be relates as single “corrosion” feature matching. Once, the features are matched, they are aligned (i.e., determining the corrosion development information). This data alignment (i.e., updating the historical corrosion data) is necessary to follow the corrosion development for each corrosion feature.

In step 220, a future corrosion profile of the pipeline is predicted using a machine learning model based at least a part of the inspection profile of the pipeline and the physical flow profile of the pipeline. The machine learning model may be any suitable machine learning model able to process and predict time-series data (e.g., any suitable regression model like a linear regression model or neural networks like recurrent neural networks (RNNs), Long Short-Term Memory (LSTM) or gated recurrent units (GRUs)). Step 220 may refer to the AI workflow 121 of the process 100. The predicted future corrosion profile of the pipeline may include at least one future corrosion feature. A future corrosion feature may include at least one of a location of a corrosion, a corrosion growth rate, a corrosion depth and/or a corrosion severity level. The machine learning model used for predicting the future corrosion profile may be trained according to a computer-implemented method for training a machine learning model for predicting a future corrosion profile of a pipeline according to aspects of the present invention. Such a method may comprise the steps of inputting training data to the machine learning model to train the machine learning model. The training data may include a plurality of time-series data samples (i.e., each sample being time-stamped). Each data sample may comprise a pipeline inspection profile of a pipeline (for a given time stamp) and a physical flow profile of the pipeline and a corresponding future corrosion profile of the pipeline for a future time stamp.

While during application of the trained model, the future corrosion profile to be predicted is unknown, the future corrosion profile during training is known to be able to optimize the model. Therefore, the corresponding future corrosion profile of the pipeline may correspond to another inspection profile of the same pipeline having a future time stamp. The problem to be solved by the machine learning model may relate to time-series prediction/regression task. Therefore, during training, the machine learning model is trained to predict a future corrosion profile (e.g., a pipeline inspection profile for time-stamp t+1) based on a pipeline inspection profile of time-stamp t plus the corresponding physical flow profile. Accordingly, once the machine learning is trained, it can then predict a future corrosion profile of a pipeline based on a (current) inspection profile and physical flow profile of the pipeline.

The pipeline inspection profile may include operating data of the pipeline, geometric configuration data of the pipeline, historical corrosion data of the pipeline and/or chemical composition data of a medium flowing through the pipeline. For example, the pipeline inspection profile may include historical corrosion data comprising a plurality of historical corrosion features. The method may then extract for each historical corrosion feature corresponding physical parameters from the physical flow profile based on the location of the historical corrosion feature (e.g., a wall shear stress of the pipeline for the given location of the corresponding corrosion feature). Accordingly, the machine learning model may learn the correlation between a state of the pipeline (e.g., an inspection profile at time-stamp t plus the corresponding physical parameters) and the corresponding follow up state (i.e., the future corrosion profile) of the pipeline (e.g., the inspection profile at time-stamp t+1 of the pipeline). For validating the accuracy of the machine learning model, the training data may be split into training set (e.g., 80% of the plurality of data samples) and a test set (e.g., 20% of the plurality of data samples). Once the machine learning model is trained on the training set, its prediction accuracy is determined on the test set based on. Based on the prediction accuracy it may be determined whether the training is finished or further optimization (e.g., adapting of hyper-parameters or training for further epochs) is required. Determining the prediction accuracy is done by putting a data sample of the test set (e.g., an inspection profile for a given time stamp i and a corresponding physical flow profile) into the machine learning model and receiving a predicted future corrosion profile from the model for a follow up timestamp i+n (referred to as prediction data), wherein n may represent a selected time for which the corrosion profile is to be predicted. For example, if a timestamp of the inspection profile is the year 2013 (i.e., i=2013) and one wants to predict a future corrosion profile for the year 2015, n equals 2 years (i.e., 2013 +2=2015). The value of n may be variable. The predicted future corrosion profile may then be validated using a follow up data sample (i.e., an inspection profile of the pipeline for the given time-stamp). In the example, the predicted future corrosion profile for the year 2015 would be validated against the actual inspection profile of the year 2015. If the difference between the predicted future corrosion profile and the actual inspection profile is within a certain threshold, the prediction quality of the model may be sufficiently high and thus the training of the model may be finished. The threshold may be a 90% accuracy (or 10% error). The difference may be determined for example by comparing properties of a future corrosion feature (e.g., the corrosion depth and location) with properties of the corresponding corrosion feature of the actual inspection profile. This may be done for all pairs of corrosion features (i.e., a future corrosion feature and the corresponding (historical) corrosion feature). The prediction quality may then be determined using all comparison results (e.g., mean over all differences).

As already mentioned, the data of the inspection profile may be continuously updated. Therefore, once an update has been conducted the machine learning model may be retrained. Before training the machine learning model, preprocessing (e.g., variable selection, treatment of missing values and/or outliers etc.) of the training data may be conducted.

After the future corrosion profile has been predicted in step 220, an operation instruction may be determined in the optional step 230 based on the future corrosion profile. For example, if a future corrosion profile of a pipeline contains three future corrosion features, an inspection schedule (e.g., ILIs) for each corresponding location may be determined based for example the corrosion severity level of the corrosion features. In another example, if a corrosion severity level of a corrosion feature is too high (i.e., a corrosion depth for example exceeds a corresponding threshold or a corrosion growth rate is too high) a respective maintenance measure (e.g., replacing the corresponding joint or segment of the pipeline) may be issued.

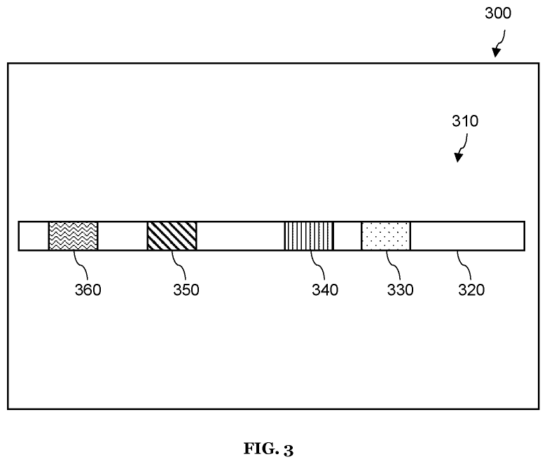

FIG. 3 illustrates a first part of a graphical user interface (GUI) 300 displaying results achieved by the present invention. The GUI 300 may be part of an interactive web-application. The web-app may be part of an underlying system (e.g., a scalable Cloud infrastructure). The system may be responsible for monitoring (i.e., collecting and updating the inspection profile(s) of the pipeline(s)) and executing analytic functions (e.g., the methods disclosed in the present invention) and displaying their corresponding results on the GUI 300 of the web-app.

In the center of the GUI 300, an overview of a pipeline's 320 geographical position and route is given in form of an interactive map 310. Furthermore, each part 330-360 of the pipeline 320 is visualized according to a corrosion severity level. The data necessary for visualizing may be extracted from a corresponding inspection profile of the pipeline 320. The corrosion level may either be none at part 330 (i.e., no corrosion at this part of the pipeline), low at part 340, medium at part 350 or high at part 360.

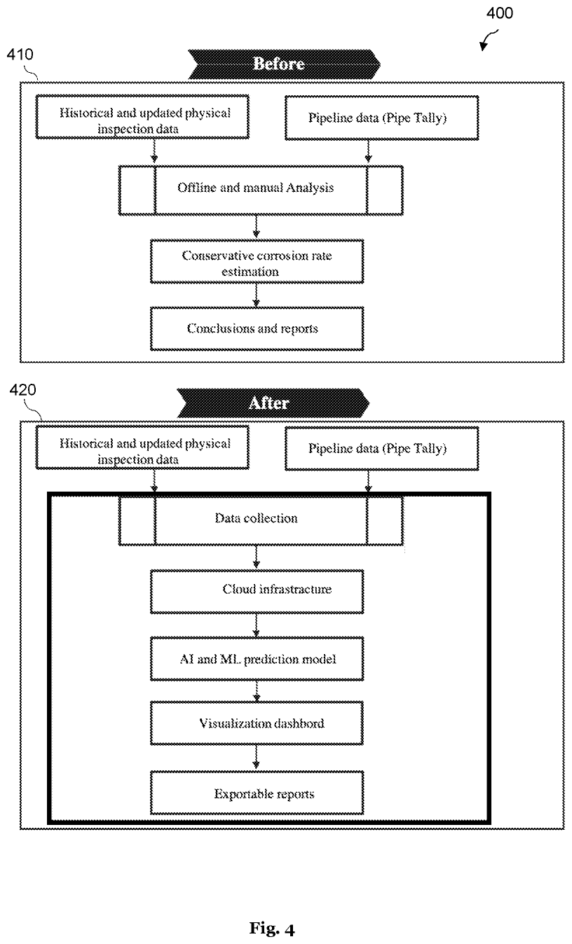

FIG. 4 illustrates an overview 400 of the improved workflow according to aspects of the present invention. FIG. 4 illustrates a “Before” workflow 410, which is used for corrosion prediction of a pipeline without using the present invention, and an “After” workflow 420, which is used for corrosion prediction according to aspects of the present invention.

As one can see at the top of FIG. 4, in the “Before” workflow 410, data from historical and updated physical inspections and data of the pipeline are combined and used for an offline and (mostly) manual analysis. The data may for example be stored in excel sheets or other data sources. Using conservative corrosion rate estimation techniques, conclusions about the corrosion of the pipeline are drawn and bundled in a report (e.g., in Word or PDF format). However, this workflow 410 does not provide interactive data visualization like 3D-displaying of geo-localization information of the pipeline allowing for displaying meta-data, process parameters or working conditions of the pipeline in real-time (e.g., as descripted with respect to FIG. 3 using the web-app) and triggering of corresponding operation instructions like scheduling of ILIs or maintenance measures.

As one can see at the bottom of FIG. 4, the “After” workflow 420 provides this functionality. Automated data collection ensures that all necessary data is continuously aggregated and provided for the cloud infrastructure. This may include pre-processing (e.g., data cleaning like removing missing not-a-number (NAN-)s or not-available data, correct inconsistencies like typos; impute and/or interpolate missing data like the height, joint number or length and elevation angle or forecast a location class of the corrosion feature; data alignment and data matching as explained with respect to corresponding aspects of the invention) of the data from existing systems and for each corresponding pipeline. This may allow to identify and check the data integrity and if needed suggest error handling of suspect data (e.g., suspect data may be a negative corrosion growth rate between two following inspections). Based on that data, the new workflow 420 enables to predict the corrosion of a pipeline using the method 200 of the present invention. Corresponding results and insights may then be displayed on an interactive dashboard as described with respect to FIG. 3. Corresponding reports may be exported from a cloud.

The aspects according to the present invention may be implemented in terms of a computer program which may be executed on any suitable data processing device comprising means (e.g., a memory and one or more processors operatively coupled to the memory) being configured accordingly. The computer program may be stored as computer-executable instructions on a non-transitory computer-readable medium.

Embodiments of the present disclosure may be realized in any of various forms. For example, in some embodiments, the present invention may be realized as a computer-implemented method, a computer-readable memory medium, or a computer system.

In some embodiments, a non-transitory computer-readable memory medium may be configured so that it stores program instructions and/or data, where the program instructions, if executed by a computer system, cause the computer system to perform a method, e.g., any of the method embodiments described herein, or, any combination of the method embodiments described herein, or, any subset of any of the method embodiments described herein, or, any combination of such subsets.

In some embodiments, a computing device may be configured to include a processor (or a set of processors) and a memory medium, where the memory medium stores program instructions, where the processor is configured to read and execute the program instructions from the memory medium, where the program instructions are executable to implement any of the various method embodiments described herein (or, any combination of the method embodiments described herein, or, any subset of any of the method embodiments described herein, or, any combination of such subsets). The device may be realized in any of various forms.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. In particular, with reference to the appended claims, features from dependent claims may be combined with those of the independent claims and features from respective independent claims may be combined in any appropriate manner and not merely in the specific combinations enumerated in the appended claims.

1. A computer-implemented method (200) for predicting corrosion of a pipeline, wherein the method comprises the steps of:
generating, using a physical simulation model, a physical flow profile of the pipeline based on at least a part of an inspection profile of the pipeline;
predicting, using a machine learning model, a future corrosion profile of the pipeline including at least one future corrosion feature based on at least a part of the inspection profile of the pipeline and the physical flow profile of the pipeline;
wherein the inspection profile includes operating data of the pipeline comprising inspection data from at least one physical inspection of the pipeline.

2. The method of claim 1, wherein the method further comprises:
determining an operation instruction for the pipeline based on the future corrosion profile.

3. The method of claim 1, wherein the physical simulation model used for generating the physical flow profile is a computational fluid dynamic, CFD, model and/or a finite element analysis, FEA, model; and/or
wherein the physical flow profile includes at least one of: a flow distribution of the pipeline; a velocity profile of the pipeline; a wall shear stress, WSS, of the pipeline; a pressure profile of the pipeline; a pressure drop of the pipeline; and/or a temperature profile of the pipeline.

4. The method of claim 1, wherein the inspection profile of the pipeline further includes at least one of: geometric configuration data of the pipeline; historical corrosion data of the pipeline; and/or chemical composition data of a medium flowing through the pipeline.

5. The method of claim 4, wherein the geometric configuration data of the pipeline comprises at least one of: a pipeline type; a coating material of the pipeline; a construction configuration of the pipeline comprising one or more segments and/or joints, each having a corresponding ID; and/or one or more of:
a design life, geographical coordinates, a length, a diameter, a nominal thickness, material, height and/or elevation angle of the pipeline.

6. The method of claim 1, wherein each inspection data comprises at least one of: a pipeline inlet injection pressure, velocity, temperature and/or mass flow rate; a pipeline design pressure and or temperature allowance; a fluid mixture density, viscosity and/or temperature; a pipeline outlet pressure, velocity and/or mass flow rate; and/or a pipeline internal wall roughness.

7. The method of claim 4, wherein the historical corrosion data comprises inspection data from at least one physical inspection of the pipeline; wherein each inspection data comprises at least one historical corrosion feature; and wherein each historical corrosion feature comprises at least one of:
x, y and/or z cartesian coordinates on the pipeline; geographical coordinates; circumferential position on the pipeline; a corrosion type; information about the position of the corrosion being internal or external to the pipeline; dimensional information, a location class, an upstream distance from a closest girth weld; a join ID and length; and/or a wall nominal thickness.

8. The method of claim 7, wherein the method further comprises:
determining, for each historical corrosion feature of an inspection data of a first physical inspection of the pipeline, a corrosion growth rate, a wall metal loss and/or an exposure time;
adding the corrosion growth rate, the wall metal loss and/or the exposure time to the corresponding historical corrosion feature; and
wherein determining the corrosion growth rate, the wall metal loss and/or the exposure time of the corresponding historical corrosion feature comprises:
comparing the corresponding historical corrosion feature with inspection data of a second physical inspection; and
wherein the second physical inspection has been conducted prior to the first physical inspection.

9. The method of claim 4, wherein the chemical composition data comprises inspection data from at least one physical inspection of the pipeline; and wherein each inspection data comprises at least one of: CO₂ concentration; H₂S concentration, and/or H₂O content percentage.

10. The method of claim 1, wherein the method further comprises:
determining that new inspection data of a physical inspection of the pipeline is available; and
generating an updated inspection profile by updating the inspection profile of the pipeline by adding the new inspection data to the inspection profile.

11. The method of claim 1, wherein each future corrosion feature of the future corrosion profile includes at least one of: a location of a corrosion; a corrosion growth rate, a corrosion depth, and a corrosion severity level.

12. The method of claim 1, wherein the machine learning model is trained according to the following steps:
inputting training data to the machine learning model to train the machine learning model;
wherein the training data includes a plurality of time-series data samples, each data sample comprising:
a pipeline inspection profile of a pipeline and a physical flow profile of the pipeline; and
a corresponding future corrosion profile of the pipeline.

13. The method of claim 12, wherein the machine learning model is retrained using the updated inspection profile.

14. A computer-implemented method for training a machine learning model for predicting a future corrosion profile of a pipeline, wherein the method comprises:
inputting training data to the machine learning model to train the machine learning model;
wherein the training data includes a plurality of time-series data samples, each data sample comprising:
a pipeline inspection profile of the pipeline and a physical flow profile of the pipeline; and
a corresponding future corrosion profile of the pipeline.

15. The method of claim 14, wherein training the machine learning model further comprises:
learning, by the machine learning model, to predict the corresponding future corrosion profile of the pipeline based on the pipeline inspection profile and the physical flow profile of the pipeline.

16. The method of claim 14, wherein training the machine learning model further comprises validating the machine learning model, wherein validating comprises:
inputting test data into the machine learning model, the test data comprising a plurality of time-series test data samples, wherein each test data sample comprises at least an inspection profile and a physical flow profile;
receiving prediction data from the machine learning model, wherein prediction data comprises one predicted future corrosion profile for each test data sample;
determining a prediction accuracy of the machine learning model based on the prediction data; and
determining, based on the prediction accuracy, that training of the machine learning model is finished.

17. A machine learning model for predicting a future corrosion profile of a pipeline trained according to the method of claim 14.

18. A data processing device comprising means configured to perform a method according to claim 1.

19. A computer program comprising instructions, which when executed by a computer, causing the computer to carry out a method according to claim 1.
